(19) United States
(12) Patent Application Publication
(10) Pub. No.: US 2003/0203615 A1
(43) Pub. Date: Oct. 30, 2003

(54) Method for depositing barrier layers in an opening

(76) Inventors: Dean J. Denning, Del Valle, TX (US); Da Zhang, Austin, TX (US); Christopher M. Prindle, Austin, TX (US); Iraj Eric Shahvandi, Round Rock, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/132,807

(22) Filed: Apr. 25, 2002

(51) Int. Cl. H01L 21/4763

(52) U.S. Cl. 438/627; 438/643; 438/653; 438/685

(57) ABSTRACT

A method for reducing the resistance within an opening, such as a via, in a dielectric (230) is described herein. A first barrier layer (250) is formed within the opening and the portion of the first barrier layer (250) at the bottom of the opening is removed, thereby exposing an underlying metal line (210). Deposited within the opening over the first barrier layer (250) and in contact with a conductor (210), a thin second barrier layer (260) forms a barrier between the conductor (210) and subsequently formed conductive material (270 and 280) within the opening. Because the second barrier layer (260) is thin, resistance is minimized between the conductor (210) and the conductive material (270 and 280). Additionally, if the opening is not aligned with the metal line (210), the second barrier layer (260) prevents the conductive material (270 and 280) from degrading an underlying dielectric (220) that may be present underneath the opening.

### FIELD OF THE INVENTION

The present invention relates generally to semiconductor processes, and more particularly to physical vapor deposition of barrier layers in conjunction with via formation.

### BACKGROUND OF THE INVENTION

With the decreasing dimensions and increasing aspect ratios of many semiconductor features, it is becoming increasingly difficult to preserve conformality of metal films deposited inside of vias, trenches and similar features. Metal films are commonly deposited using a conventional physical vapor deposition (PVD) or ionized physical vapor deposition (iPVD) process. When depositing metals using one of these two techniques, excess metal is often deposited in certain areas of the feature, while not enough metal is deposited in other areas of the feature.

Particular problems are encountered when an excessively thick layer of metal is deposited at the bottom of features such as vias and trenches, and when too much metal is deposited at the opening of these features. For example, an excessively thick barrier layer of tantalum at the bottom of a via can result in a high via resistance, while too much metal deposited at the opening of a via can reduce the amount of metal being deposited on the walls of the via. This uneven deposition of metals is often referred to as non-conformality, and much effort has been devoted to minimizing its effects.

For example, in order to minimize breadloafing, i.e. the accumulation of material at the opening of a via, which can prevent uniform material deposition within the opening, a technique called corner clipping is sometimes employed prior to metal deposition. Corner clipping removes material (e.g. dielectric material) from the top corners of features thereby limiting metal build up in that region that can consequently over-shadow or block access to the inside walls of the feature.

In order to reduce the thickness of the metal deposited at the bottom of features such as vias and trenches using iPVD, process parameters such as wafer power, target power, coil power, etc. can be adjusted to increase the sputtering effect of plasma ions.

Other proposed techniques to reduce via resistance involve sputtering out either all or a portion of the barrier layer at the bottom of via. But these proposals are not particularly manufacturable because barrier layer thickness in the vias will vary within an individual device due to varying via aspect ratios. Thus, a sputter process to remove the barrier layer from the bottom of the vias will inevitably either sputter away too much or too little material within some of the vias. Consequently, the resulting via resistance will vary and have too large of a distribution for a controllable manufacturing process.

Therefore, what is needed is an improved way to controllably reduce via resistance regardless of aspect ratio. It is also important for such improvement to provide other necessary via attributes, such as adequate conformality of deposited metal and sufficient metal diffusion barrier properties.

### BRIEF DESCRIPTION OF THE DRAWINGS

The present invention is illustrated by way of example and not limitation in the accompanying figures, in which like references indicate similar elements, and in which:

FIGS. 1-4 are cut away cross-sectional views of a via formation process in accordance with one embodiment of the present invention.

For simplicity and clarity of illustration, the figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help to improve understanding of embodiments of the present invention. Also, the same reference numerals in different figures denote the same elements.

Furthermore, the terms first, second, and the like in the description and in the claims, if any, are used for distinguishing between similar elements and not necessarily for describing a sequential or chronological order. It is further understood that the terms so used are interchangeable under appropriate circumstances such that the embodiments of the invention described herein are, for example, capable of operation in other sequences than illustrated or otherwise described herein.

### DETAILED DESCRIPTION

While many proposals have been presented to overcome problems associated with non-conformal deposition of metal in vias and other openings in integrated circuit fabrication, there continues to be a need for improvement in this area. The present invention particularly focuses upon solving problems which were discovered in using re-sputtering techniques in a via formation process used in conjunction with copper interconnect technology.

For example, in partially sputtering away a barrier layer at the bottom of a via, it was discovered that the resulting thinned barrier layer had non-uniform thicknesses due to differing aspect ratios of the vias within a device. This results in varying via resistance. In fully sputtering away a barrier layer at the bottom of a via, problems are incurred when trying to form “unlanded” vias which inevitable occur in a device, either intentionally by design or unintentionally due to misalignment. When using unlanded vias, the sputtering removes the barrier layer from adjacent dielectric materials, creating a path for copper diffusion into the dielectric material after the via is filled with copper. Another problem in completely removing the barrier layer from the bottom of the via is that a path is created for electromigration of voids from one copper layer to the next. In other words, without a barrier layer in the bottom of the via to contain electromigration, a void can travel throughout all the copper layer and exacerbate the electromigration problem.

The present invention takes advantage of many of the benefits of via sputtering techniques while overcoming the aforementioned problems. In accordance with a preferred embodiment of the present invention, an initial barrier layer is deposited into a via formed in a dielectric layer. The via exposes an underlying conductive member, such as a copper interconnect. This initial barrier is then sputtered, preferably using the same tool as was used to deposit the barrier layer, so that the barrier layer is removed from the bottom of the via. Then a second barrier layer is deposited, again preferably using the same tool without breaking vacuum, to ensure solid diffusion barrier properties in and around the via, so that both landed and unlanded vias can be formed with similar properties. Electromigration problems are also overcome because the second barrier layer is sufficient to contain voids between metal layers. In using a process in accordance with the present invention, the via resistance is controlled because the second barrier layer is much thinner than the first (e.g. 50 angstroms as compared to 300 angstroms).

A further benefit in using the invention is that an RF pre-clean step which is typically performed just prior to depositing the barrier layer in the via can be eliminated. Prior to depositing the diffusion barrier, it has been deemed necessary in prior art processes to clean the surface of any exposed copper within the via to remove copper oxide and post via etch residue. An RF sputter pre-clean step, performed in the same tool as is used to deposit the barrier layer, albeit in a different chamber, is commonly used for this purpose. But an undesirable consequence of this sputter pre-clean is that the exposed copper in the via also gets sputtered and re-deposited onto the via sidewalls prior to deposition of the barrier layer. This results in copper being in direct contact with the adjacent interlayer dielectric (ILD), which leads to copper diffusion and degradation of the ILD's dielectric properties.

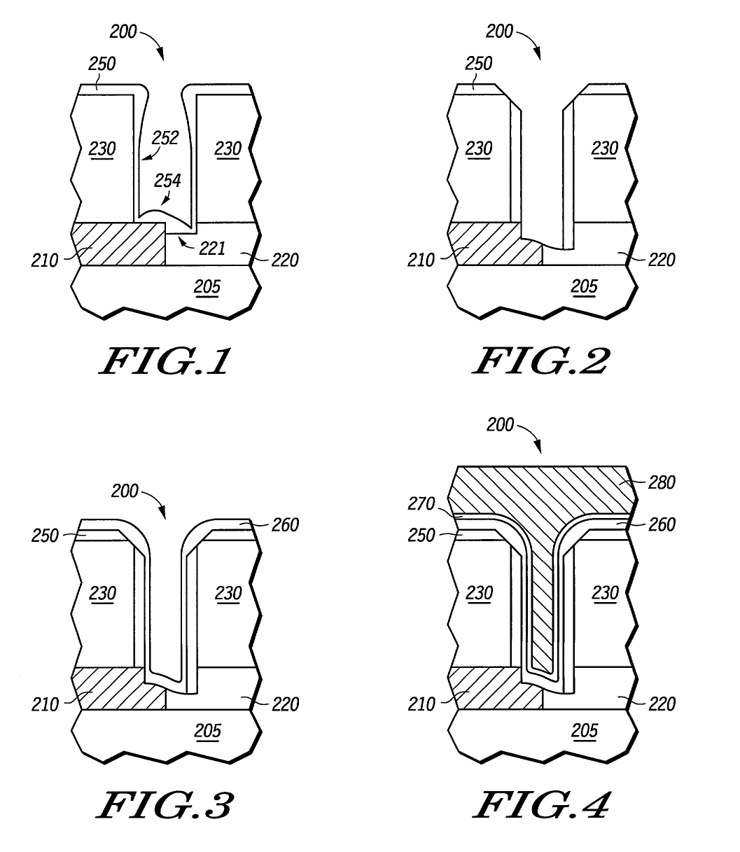

Referring to FIG. 1, the basic structure of a via 200 according to one embodiment of the present invention will be discussed. Via 200 is a semiconductor feature constructed to connect a conductor, such as metal line 210, to another conductor above the via (not illustrated in FIG. 1). Metal line 210 is formed over a substrate 205. Substrate 205 is illustrated very simply because it is not important to understanding the present invention, but it will generally include a semiconductor material having various active devices formed thereon. Metal line 210 is formed to make electrical contact to an underlying device, such as a transistor. In a preferred embodiment, metal line 210 is comprised mostly of copper. In order to construct via 200, a dielectric 230 is deposited on top of metal line 210 using a chemical vapor deposition step. Dielectric 230 effectively isolates metal line 210 from overlying conductive elements or members. Note that dielectric 230 may be deposited in a single step, or in a series of steps, and that dielectric 230 may comprise a single layer of a material or otherwise. In a preferred embodiment, dielectric 230 comprises silicon dioxide.

As shown in FIG. 1, metal line 210 is formed adjacent another dielectric 220 which can also be silicon dioxide. Forming metal line 210 adjacent dielectric 220 can be accomplished using conventional damascene processing, whereby the metal line 210 and dielectric 220 are chemically-mechanically polished to produce a planar surface.

Once dielectric 230 is deposited, the physical boundaries of via 200 are defined with dielectric 230 by photolithography masking and etch processes commonly employed by those skilled in the art. For example, in the case of silicon dioxide as the dielectric material, a conventional dry etch using a fluorine-based chemistry (e.g. CF₄) can be used to form the via. As shown in FIG. 1, via 200 is unlanded. In other words, a portion of the via directly overlies metal line 210, but the remaining portion is positioned over dielectric 220. Consequently, in etching dielectric 230 to form via 200, a portion 221 of dielectric 220 will likely be etched as well as shown since they are of the same or similar materials. Being “unlanded” means that a portion of the bottom of the via lands off the underlying conductive element to which electrical connection is being made (in this case, metal line 210).

After etching the via, a barrier layer 250 is deposited, preferably using a sputter deposition technique. Barrier layer 250 may be formed of any suitable conductive material or combination of conductive materials, and serves to prevent migration of a subsequently deposited metal layer (often copper) into the dielectric material and promote adhesion of the future metal layer to the dielectric material. In a preferred embodiment, barrier layer 250 is a layer of tantalum. Alternatively, barrier layer could be a layer of tantalum nitride, titanium, titanium nitride, tungsten, or tungsten nitride.

As is apparent in FIG. 1, barrier layer 250 is not perfectly conformal. The thickness of the barrier layer 250 over dielectric 230 (i.e. the thickness over the “field”) and at the bottom of the via is larger than that along the sidewalls of the via. This is quite common in practice, and has adverse affects. A thick barrier at the bottom of the via leads to high via resistance. A thin barrier along the sidewalls may not have sufficient integrity (e.g. it is discontinuous or may have pin-holes formed therein). If the barrier is too thin, a conductive material (e.g. copper) subsequently deposited in the opening may degrade surrounding dielectric materials through unwanted diffusion.

In accordance with the present invention, the problems associated with barrier layer 250 are overcome as shown and described in reference to the following figures. Referring now to FIG. 2, the same via 200 illustrated in FIG. 1 is shown after post deposition sputtering has been performed to remove the barrier layer 250 from the bottom of via 200. Preferably, this post-deposition sputtering is performed in the same tool and in the same chamber as was used to deposit barrier layer 250. This post-deposition sputtering is achieved by changing the process conditions. More specifically, the process is changed from a “sputter deposition state” to more of an “sputter etch state” by lowering or removing the power applied to the target of the sputtering system and increasing the bias power on the substrate. This can be accomplished in-situ, without breaking vacuum.

During the post-deposition sputtering, the barrier material which is sputtered from the bottom of the via will likely deposit onto the sidewalls of the via. Thus, as shown in FIG. 2, the sidewall thickness may actually increase during this process. This is advantageous because it improves sidewall coverage. However, the barrier layer 250 will also typically thin at top corners of the via as illustrated in FIG. 2, such that portions of dielectric 230 may be exposed. And in the case of an unlanded via, removal of the barrier layer 250 from the bottom of the via results in exposure of a portion of dielectric 220. These are undesirably consequences which are overcome in accordance with the present invention by depositing a second barrier layer 260, as illustrated in FIG. 3.

Barrier layer 260 is preferably deposited in the same tool and same chamber as was used to deposit and sputter etch first barrier layer 250. Process conditions are changed from a “sputter etch state” to more of a “sputter deposition state” by increasing target power and decreasing bias power to the substrate. Preferably the second barrier layer is deposited much thinner than the first barrier layer. For example, the second barrier layer 260 would be deposited within a range of 40-80 angstroms thick at the bottom of the via (corresponding to about 80-160 angstroms on the field) while the first barrier layer would be approximately 150-180 angstroms at the bottom of the via (corresponding to about 300-400 angstroms on the field). Second barrier layer 260 may be thinner than 40 angstroms on the bottom of the via (e.g. down to 20 angstroms or below), but techniques other than sputter deposition (such as atomic layer deposition, or chemical vapor deposition) may have to be employed to ensure barrier integrity. In a preferred embodiment, second barrier layer 260 is tantalum. Alternatively, tantalum nitride, titanium, titanium nitride, tungsten, or tungsten nitride could be used. In a preferred embodiment, the first barrier layer 250 and the second barrier layer 260 are of the same material and are of tantalum. In another embodiment, the first barrier layer 250 is formed from a layer of tantalum nitride and the second barrier layer 260 is formed from a layer of tantalum.

While deposition and sputtering of barrier layer 250 are preferably done in the same tool and same chamber for reasons of throughput and cycle time advantage, use of different chambers for these two steps may be advantageous for other reasons, and are considered within the scope of the invention. However, it is preferable in using multiple chambers to keep the wafer under vacuum in moving from one chamber to another (thus an in-situ transfer within a single multi-chamber tool is preferred).

After the second barrier layer 260 has been formed, via 200 is filled with a conductive metal material 280, for example copper, as shown in FIG. 4. Prior to depositing conductive metal material 280, a conductive seed layer 270 can be deposited, which serves as a starting seed material for electroplating conductive metal material 280. The portions of the stack of conductive metal material 280, seed layer 270 and barrier layers 260 and 250 that lie above the dielectric 230 (i.e. those portions in the field area) can then be polished off to planarize the device prior to deposition of the next level metal.

As is apparent from the structure shown in FIG. 4, second barrier layer 260 enhances barrier protection properties within via 200 by ensuring there is no path for copper diffusion into surrounding dielectric materials. Therefore, thinning of the first barrier layer at top corners of the via is no longer a problem, and unlanded vias can be formed without copper diffusion concerns. It is also apparent that barrier layer 260 adequately separates copper in metal line 210 from direct contact with conductive metal material 280 (and conductive seed layer 270, if present). The benefit of this separation is suppression of electromigration failures. The barrier layer prevents voids from one metal layer migrating to another overlying or underlying metal layer.

A further benefit in using the invention, as mentioned briefly above, is that an RF pre-clean step which is typically performed just prior to depositing the barrier layer in the via can be eliminated. An undesirable consequence of this sputter pre-clean is that the exposed copper in the via also gets sputtered and re-deposited onto the via sidewalls prior to deposition of the barrier layer. This results in copper being in direct contact with the adjacent interlayer dielectric (ILD), which leads to copper diffusion and degradation of the ILD's dielectric properties. With the present invention, such a pre-clean step can be eliminated. The purpose of the pre-clean process is primarily to remove contaminates from the exposed portions of the metal layer at the bottom of the via prior to barrier layer deposition. With the invention, these contaminants can be removed after the initial barrier layer deposition, during the sputter etch process used to removed the barrier layer from the bottom of the via. Accordingly, any copper which is deposited on the via sidewalls as a result of the sputter etch process will occur after the initial barrier layer is formed and will not result in copper being in direct contact with the surrounding dielectric material.

In the foregoing specification, the invention has been described with reference to specific embodiments. However, one of ordinary skill in the art appreciates that various modifications and changes can be made without departing from the scope of the present invention as set forth in the claims below. For example, while the present invention finds particularly applicability to physical vapor deposition (PVD) techniques, the invention is not limited to use with PVD. Other techniques, such as chemical vapor deposition (CVD), and atomic layer deposition (ALD) may experience benefits from the invention as well. Also, while the term “via” has been used throughout the description, it is apparent that the invention can be used in conjunction with any feature to be filled with a conductive material, such as a trench. Similarly, a conductor which the via exposes need not be a metal line, but can instead be of a conductive semiconductor material (e.g. doped polysilicon as is used for transistor gate electrodes) or any other electrically conductive material. Accordingly, the specification and figures are to be regarded in an illustrative rather than a restrictive sense, and all such modifications are intended to be included within the scope of present invention.

1. A method for forming barrier layers in an opening comprising:
providing a substrate having a conductor;
forming a dielectric layer over the conductor;
forming the opening through the dielectric layer to expose the conductor, the opening having a bottom and sidewalls;
depositing a first barrier layer in the opening;
etching the first barrier layer to remove the first barrier layer from the bottom of the opening; and
depositing a second barrier layer in the opening and over remaining portions of the first barrier layer.

2. The method of claim 1, wherein:
depositing the first barrier layer comprises sputter depositing the first barrier layer;
etching the first barrier layer comprises sputter etching the first barrier layer; and
depositing the second barrier layer comprises sputter depositing the second barrier layer.

3. The method of claim 2 wherein sputter depositing the first barrier layer is performed without an immediately preceding sputter pre-clean operation.

4. The method of claim 2, wherein sputter etching the first barrier layer comprises removing a portion of the first barrier layer on the bottom of the opening and depositing the portion of the first barrier layer onto the sidewalls of the opening.

5. The method of claim 2, wherein both the first barrier layer and the second barrier layer comprise a material selected from the group consisting of tantalum, titanium, tantalum nitride, titanium nitride, tungsten, and tungsten nitride.

6. The method of claim 2, wherein the first barrier layer and the second barrier layer are formed of a same material.

7. The method of claim 2, wherein sputter depositing the first barrier layer, sputter etching the first barrier layer, and sputter depositing the second barrier layer are performed in a same processing chamber in-situ.

8. The method of claim 2, wherein sputter depositing the first barrier layer and sputter etching the first barrier layer are performed in a different processing chambers.

9. The method of claim 1, wherein the first barrier layer and the second barrier layer are formed of different materials.

10. The method of claim 9, wherein the first barrier layer is tantalum nitride and the second barrier layer is tantalum.

11. The method of claim 1, wherein the second barrier layer is less than approximately 80 angstroms in thickness at the bottom of the opening.

12. The method of claim 1, wherein sputter etching the first barrier layer further comprises removing the first barrier layer on at least one corner of the opening.

13. The method of claim 1, wherein sputter depositing a second barrier layer further comprises sputter depositing the second barrier layer on the at least one corner of the opening.

14. The method of claim 1, further comprising depositing a copper seed layer over the second barrier layer, wherein a thickness of the second barrier layer when depositing the copper seed layer is substantially a same thickness as when the second barrier layer was deposited.

15. The method of claim 14, further comprising filling the opening with copper by electroplating.

16. The method of claim 1, wherein:
the dielectric layer is a first dielectric layer;
the substrate further comprises a second dielectric layer adjacent to the conductor; and
forming the opening further comprises exposing a portion of the second dielectric layer.

17. A method for forming barrier layers in an opening comprising:
providing a substrate having a conductor;
forming an dielectric layer over the conductor;
forming an opening through the dielectric layer, the opening having a bottom and sidewalls;
forming a first barrier layer in the opening, the first barrier layer having a thickness at the bottom of the opening;
exposing the conductor in the opening by sputter etching the first barrier layer from the bottom of the opening;
forming a second barrier layer in the opening and over the first barrier layer, wherein the second barrier layer has a second thickness at the bottom of the opening; and
forming a conductive layer over the second barrier layer, wherein a thickness of the second barrier layer at the bottom of the opening when forming the conductive layer remains the second thickness.

18. The method of claim 17, wherein:
the dielectric layer is a first dielectric layer;
the substrate further comprises a second dielectric layer adjacent to the conductor; and
forming the opening further comprises exposing a portion of the second dielectric layer.

19. The method of claim 17, wherein both the first barrier layer and the second barrier layer comprise a material selected from the group consisting of tantalum, titanium, tantalum nitride, titanium nitride, tungsten, and tungsten nitride.

20. The method of claim 19, wherein the first barrier layer and the second barrier layer are formed of a same material.

21. The method of claim 19, wherein the first barrier layer and the second barrier layer are formed of different materials.

22. The method of claim 21, wherein the first barrier layer is tantalum nitride and the second barrier layer is tantalum.

23. The method of claim 17, wherein the second barrier layer is less than approximately 80 angstroms in thickness at the bottom of the opening.

24. The method of claim 17, wherein forming the first barrier layer in the opening, exposing the conductor in the opening, forming the second barrier layer in the opening are performed within a same sputtering tool.

25. The method of claim 24, wherein forming the first barrier layer in the opening, exposing the conductor in the opening, and forming the second barrier layer in the opening are performed in-situ in a same sputtering chamber of the same sputtering tool.

26. The method of claim 25 wherein forming the first barrier layer is performed by sputter deposition without an immediately preceding sputter pre-clean operation.

27. The method of claim 24, wherein forming the first barrier layer in the opening, and exposing the conductor in the opening are performed different chambers of a same sputtering tool.

28. The method of claim 17, further comprising filling the opening with copper after forming the second barrier layer.

29. A method for forming barrier layers within a semiconductor device comprising:
forming a first dielectric layer over a semiconductor substrate;
forming a conductor adjacent to the first dielectric layer;
forming a second dielectric layer overlying the first dielectric layer and the conductor;
forming an opening within the second dielectric layer, wherein the opening has sidewalls and a bottom;
sputter depositing a first barrier layer along the sidewalls and bottom of the opening;
sputter etching the first barrier layer from the bottom of the opening to expose a portion of the conductor;
sputter depositing a second barrier layer within the opening, wherein a portion of the second barrier layer is in contact with the portion of the conductor; and
depositing a conductive layer over the second barrier layer without removing the second barrier layer from within the opening.

30. The method of claim 29, wherein the second barrier layer has a thickness at the bottom of the opening that is approximately less than 80 angstroms.

31. The method of claim 29, wherein the first barrier layer is tantalum nitride and the second barrier layer is tantalum.

32. The method of claim 29, wherein the first barrier layer and the second barrier layer are both tantalum layers.

33. The method of claim 29, wherein
sputter depositing the first barrier layer comprises resputtering the first barrier layer from the bottom of the opening to the sidewalls of the opening to increase a thickness of the sidewall coverage while exposing the portion of the conductor.

34. The method of claim 29, wherein sputter depositing the first barrier layer, sputter etching the first barrier layer, and sputter depositing the second barrier layer are performed in-situ in a same sputtering chamber of a same tool.

35. The method of claim 34 wherein sputter deposition the first barrier layer is performed without an immediately preceding sputter pre-clean operation.

36. The method of claim 29, wherein sputter depositing the first barrier layer and sputter etching the first barrier layer are performed in different chambers of a same tool.
